(19) United States
(12) Patent Application Publication
(10) Pub. No.: US 2026/0239627 A1
(43) Pub. Date: Aug. 13, 2026

(54) SEMICONDUCTOR DEVICE AND METHOD FOR MANUFACTURING THE SAME

(71) Applicant: MACRONIX INTERNATIONAL CO., LTD., Hsinchu (TW)

(72) Inventors: Erh-Kun LAI, Taichung County (TW); Wei-Chih CHIEN, Hsinchu City (TW); Hsiang-Lan Lung, Kaohsiung City (TW)

(21) Appl. No.: 19/052,412

(22) Filed: Feb. 13, 2025

(51) Int. Cl. H10B 63/00

(52) U.S. Cl. CPC H10B 63/24

(57) ABSTRACT

A semiconductor device includes a bottom plate, a stack, a conductive pillar, a protecting layer and a memory layer. The stack is stacked on the bottom plate along a first direction. The stack includes insulating layers and conductive layers alternately stacked on the bottom plate along the first direction. The conductive pillar extends along the first direction and passes through at least a portion of the stack. The protecting layer extends along the first direction, surrounds the conductive pillar and is disposed between the conductive pillar and the conductive layers. A resistance of the protecting layer is higher than a resistance of the conductive layers. The memory layer surrounds the protecting layer and is disposed between the protecting layer and the conductive layers.

### BACKGROUND OF THE INVENTION

### Field of the Invention

The invention relates in general to a semiconductor device and a method for manufacturing the semiconductor device, and more particularly to a memory device and a method for manufacturing the memory device.

### Description of the Related Art

Recently, the demand for three-dimensional memory devices has become higher and higher. One type of 3D memory device is, for example, 3D ovonic threshold switching memory (3D OTS memory). The ovonic threshold switch has a bipolar material, and a turn-on state can be formed when a threshold voltage (Vt) is reached, and the resistance is greatly reduced. When the voltage drops below the threshold voltage, the high resistance is restored, and a turn-off state can be formed. The 3D OTS memory may include a plurality of vertically stacked arrays of memory cells. However, current 3D OTS memories still face some electrical problems. For example, surge current is easily generated during the process of reading memory cells.

### SUMMARY OF THE INVENTION

The invention is directed to the improvement of three-dimensional threshold switching memory (3D OTS memory), especially reducing the surge current to avoid damage to components and increase the stability of the system.

According to some embodiments of the present invention, a semiconductor device is provided. The semiconductor device includes a bottom plate, a stack, a conductive pillar, a protecting layer and a memory layer. The stack is stacked on the bottom plate along a first direction. The stack includes insulating layers and conductive layers alternately stacked on the bottom plate along the first direction. The conductive pillar extends along the first direction and passes through at least a portion of the stack. The protecting layer extends along the first direction, surrounds the conductive pillar and is disposed between the conductive pillar and the conductive layers. A resistance of the protecting layer is higher than a resistance of the conductive layers. The memory layer surrounds the protecting layer and is disposed between the protecting layer and the conductive layers.

According to some embodiments of the present invention, a method for manufacturing a semiconductor device is provided. The method includes the following steps. A bottom plate is provided. A stack is formed on the bottom plate along the first direction. The stack includes insulating layers and conductive layers alternately stacked on the bottom plate along the first direction. A conductive pillar is formed. The conductive pillar extends along the first direction and passes through at least a portion of the stack. A protecting layer is formed. The protecting layer extends along the first direction, surrounds the conductive pillar and is disposed between the conductive pillar and the conductive layers. A resistance of the protecting layer is higher than a resistance of the conductive layers. A memory layer is formed. The memory layer surrounds the protecting layer and is disposed between the protecting layer and the conductive layers.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIG. 1 illustrates a cross-sectional view of a semiconductor device according to an embodiment of the present invention.

FIG. 2 illustrates a cross-sectional view of a semiconductor device according to another embodiment of the present invention.

FIGS. 3A to 3F illustrate a flow chart of a method for manufacturing the semiconductor device in FIG. 2.

FIG. 4 illustrates a cross-sectional view of a semiconductor device according to another embodiment of the present invention.

FIG. 5 illustrates a cross-sectional view of a method for manufacturing the semiconductor device of FIG. 4

### DETAILED DESCRIPTION OF THE INVENTION

Various embodiments will be described in more detail below with reference to the accompanying drawings. The narrative content and diagrams are provided for illustration only and are not intended to be limiting. For clarity, some elements and/or symbols may be omitted in some drawings. In addition, elements in the drawings may not be drawn to actual scale. It is contemplated that elements and features in one embodiment can be advantageously incorporated into another embodiment without further description.

According to some embodiments, a semiconductor device of the present invention can be applied to a three-dimensional ovonic threshold switching (OTS) memory, such as a three-dimensional OTS only memory (3D OTS only memory), but the present invention is not limited thereto. The 3D OTS only memory uses only OTS components, and the OTS components is used as storage units and as selection components. The 3D OTS only memory does not require additional transistors or other components to control the reading and writing of data.

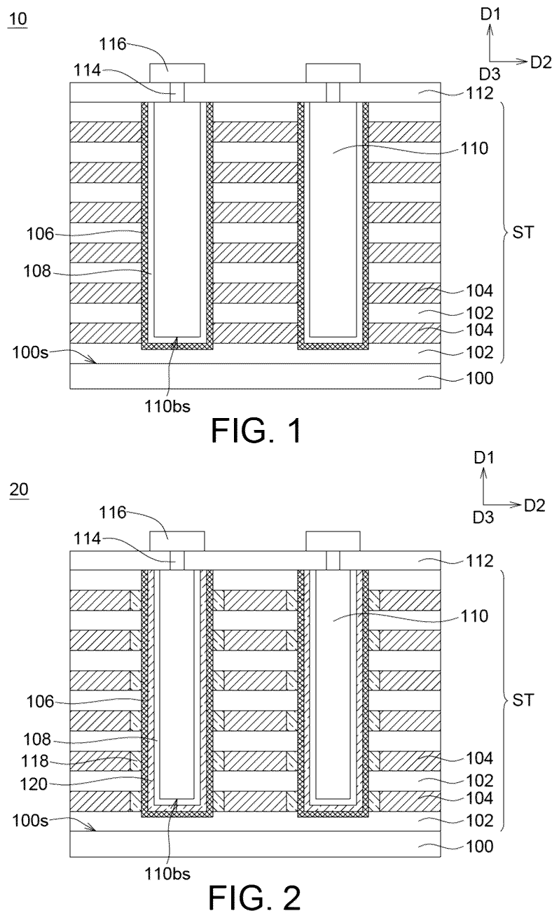

FIG. 1 illustrates a cross-sectional view of a semiconductor device 10 according to an embodiment of the present invention.

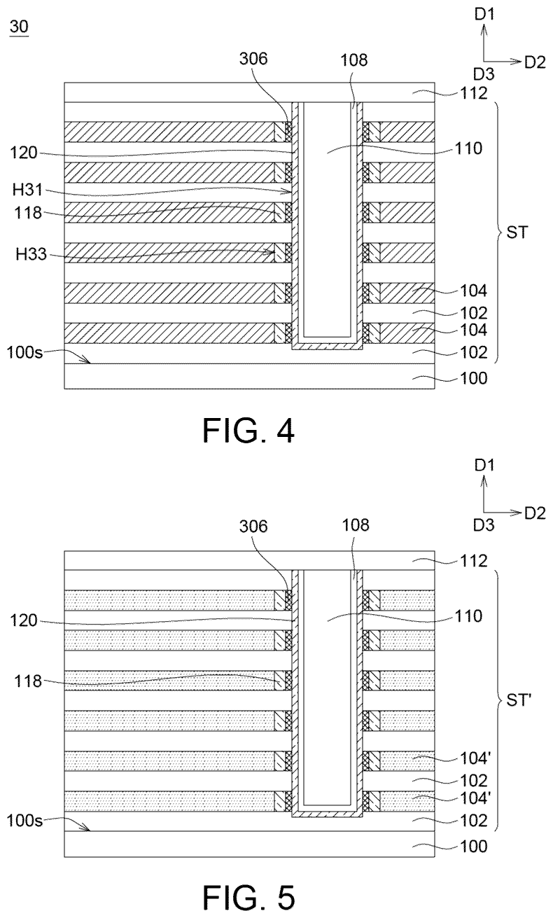

Referring to FIG. 1, the semiconductor device 10 includes a bottom plate 100, a stack ST, a conductive pillar 110, a protecting layer 108 and a memory layer 106. The stack ST is stacked on the bottom plate 100 along a first direction D1. The stack ST includes a plurality of insulating layers 102 and a plurality of conductive layers 104. The insulating layers 102 and the conductive layers 104 are alternately stacked on the bottom plate 100 along the first direction D1. In the present embodiment, the first direction D1 is, for example, a normal direction parallel to an upper surface 100s of the bottom plate 100. The bottommost layer and the topmost layer of the stack ST are both insulating layers 102, but the invention is not limited thereto. The material of the conductive layer 104 includes conductive materials, which are tantalum nitride (TaN), tungsten nitride (WN), titanium nitride (TiN), tungsten (W), aluminum (Al), copper (Cu), ruthenium (Ru), cobalt (Co), cobalt silicide (CoSi_{X}), titanium silicide (TiSi_{X}), nickel (Ni), nickel silicide (NiSi_{X}), platinum (Pt) or an arbitrary combination thereof. The material of the insulating layer 102 may include a dielectric material, such as an oxide. In some embodiments, the conductive layer 104 may be a lower resistance conductor, and formed by Atomic Layer Deposition (ALD) or Chemical Vapor Deposition (CVD), which is a very conformal process due to filling a conductive material into the spaces formed by the removal of sacrificial layers 104′ (as shown in FIG. 5 detailed below).

The conductive pillar 110 extends along the first direction D1 and passes through at least part of the stack ST. In the present embodiment, a bottom surface 110bs of the conductive pillar 110 is stopped in the bottommost conductive layer 104 of the stack ST without completely penetrating the bottommost conductive layer 104 of the stack ST, and does not extend to the bottommost insulating layer 102 of the stack ST, but the invention is not limited thereto. The material of the conductive pillar 110 includes conductive materials, which are tantalum nitride (TaN), tungsten nitride (WN), titanium nitride (TiN), tungsten (W), aluminum (Al), copper (Cu), Ruthenium (Ru), cobalt (Co), cobalt silicide (CoSi_{X}), titanium silicide (TiSi_{X}), nickel (Ni), nickel silicide (NiSi_{X}), platinum (Pt) or any combination thereof. In some embodiments, the conductive pillar 110 may be formed by Atomic Layer Deposition (ALD) or Chemical Vapor Deposition (CVD), which is a very conformal process. It has good interface properties and a stable temperature property between the conductive pillar 110 and the protecting layer 108.

The protecting layer 108 extends continuously along the first direction D1, surrounds the conductive pillar 110 and is disposed between the conductive pillar 110 and the conductive layers 104, and overlaps the insulating layers 102 and the conductive layer 104 in a second direction D2 and a third direction D3, wherein the first direction D1, the second direction D2 and the third direction D3 are perpendicular to each other. In addition, the protecting layer 108 further extends along the second direction D2 and the third direction D3 to contact the bottom surface 110bs of the conductive pillar 110. The resistance of the protecting layer 108 may be higher than the resistance of the conductive layer 104 and the resistance of the conductive pillar 110. In the cross-sectional view shown in FIG. 1, the protecting layer 108 may have a U-shaped cross-section. The material of the protecting layer 108 may include higher resistance materials, which are doped polysilicon, undoped polysilicon, silicon germanium alloy (SiGeX), germanium (Ge), nitride Gallium (GaN), indium gallium zinc oxide (IGZO), indium oxide (InO), metal oxide channel material, tantalum nitride (TaN), tungsten nitride (WN), titanium nitride (TiN), carbon, doped carbon, graphene or others. In some embodiments, the protecting layer 108 may be formed by Atomic Layer Deposition (ALD) or Chemical Vapor Deposition (CVD), which is a very

### Conformal Process.

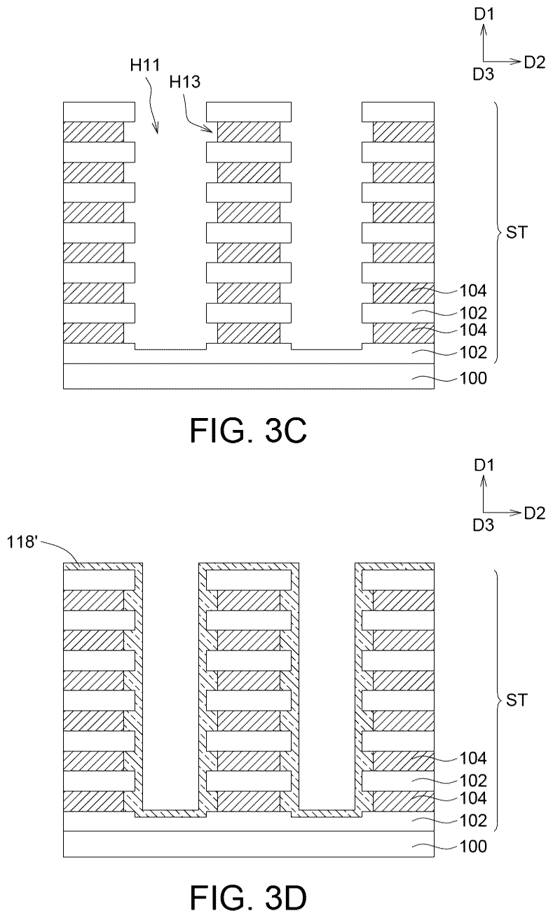

The memory layer 106 extends along the first direction D1, surrounds the protecting layer 108, and is disposed between the protecting layer 108 and the conductive layer 104. In the present embodiment, the memory layer 106 continuously extends along the first direction D1 and overlaps the insulating layer 102 and the conductive layer 104 in the second direction D2 and the third direction D3, and the memory layer 106 further extends along the second direction D2 and the third direction D3 to contact the bottom surface of the protecting layer 108, but the invention is not limited thereto. In the cross-sectional view shown in FIG. 1, the memory layer 106 may have a U-shaped cross-section. Multiple intersection locations between the memory layer 106 and the conductive layers 104 may form multiple memory cells. Memory layer 106 may include memory material for storing 0 or 1. Furthermore, the memory layer 106 can be used as an ovonic threshold switch, and its material is, for example, arsenic triselenide (As₂Se₃), zinc telluride (ZnTe) or germanium selenide (GeSe). In some embodiments, the material of the memory layer 106 may include a chalcogenide combined with one or more elements selected from the group consisting of: tellurium (Te), indium (In), gallium (Ga), selenium (Se), germanium (Ge), silicon (Si), arsenic (As), titanium (Ti), sulfur(S), antimony (Sb) and phosphorus (P). In some embodiments, the memory layer 106 may be formed by Atomic Layer Deposition (ALD) or Chemical Vapor Deposition (CVD), which is a very conformal process due to filling a memory material into first openings H11(as shown in FIG. 3B detailed below). The memory layer 106 provides 0 and 1 or multilevel properties.

The semiconductor device 10 may further include a capping layer 112, a contact 114 and a conductor layer 116. The capping layer 112 covers the stack ST. The conductor layer 116 is disposed on the capping layer 112 and extends along the third direction D3. The contact 114 passes through the capping layer 112 and is in electrical contact with the conductive pillar 110 and the conductor layer 116. That is, the conductor layer 116 is electrically connected to the conductive pillar 110 through the contact 114.

In some embodiments, the conductive layers 104 may serve as word lines, and the conductor layer 116 may serve as a bit line.

Compared with a semiconductor device without a protecting layer, since the semiconductor device of the present invention includes a protecting layer 108, and the resistance of the protecting layer 108 is higher than the resistance of the conductive layers 104, the protecting layer 108 can reduce the surge current to avoid component damage, and increase system stability. In addition, the protecting layer 108 surrounds the conductive pillars 110 and is disposed between the conductive pillar 110 and the conductive layers 104, so that the resistance can be increased locally for each of memory cells, avoiding the global increase in resistance of bit lines or word lines.

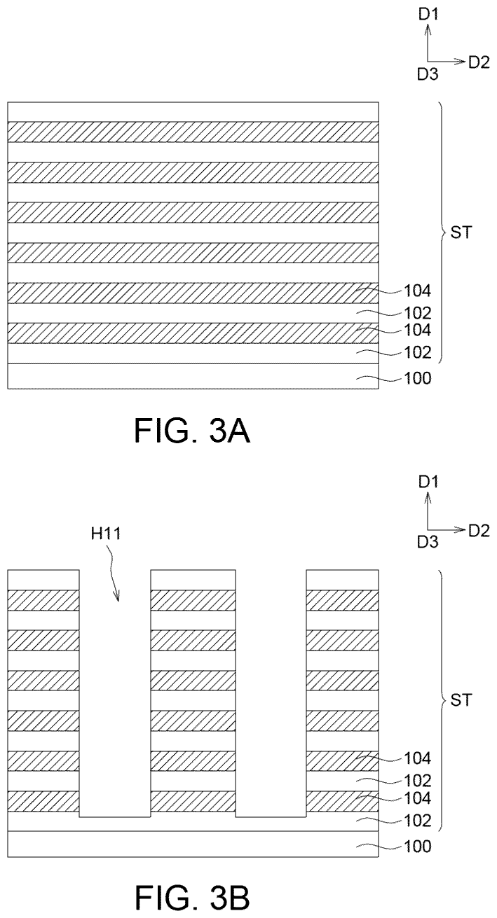

FIG. 2 illustrates a cross-sectional view of a semiconductor device 20 according to another embodiment of the present invention. The difference between the semiconductor device 20 and the semiconductor device 10 is that the semiconductor device 20 further includes a plurality of outer electrode layers 118 and an inner electrode layer 120, and other identical or similar parts will not be described in detail. Components in the semiconductor device 20 that are the same or similar to the semiconductor device 10 are labeled with the same or similar component symbols and have the same or similar structures, materials, and functions.

Referring to FIG. 2, the outer electrode layers 118 of the semiconductor device 20 is disposed between the conductive layers 104 and the memory layer 106. The outer electrode layers 118 surround the memory layer 106. Different layers of outer electrode layers 118 are separated by insulating layers 102. The inner electrode layer 120 is disposed between the memory layer 106 and the protecting layer 108, and surrounds the protecting layer 108. The inner electrode layer 120 may continuously extend along the first direction D1 and overlap the insulating layers 102 and the conductive layers 104 in the second direction D2 and the third direction D3. In addition, the inner electrode layer 120 further extends along the second direction D2 and the third direction D3 and contacts the bottom surface of the protecting layer 108. In the cross-sectional view shown in FIG. 2, the inner electrode layer 120 may have a U-shaped cross-section. The materials of the outer electrode layer 118 and the inner electrode layer 120 may respectively include a conductive material, and the conductive material is tantalum nitride (TaN), tungsten nitride (WN), titanium nitride (TiN), carbon, doped Doped carbon, graphene or others.

In some embodiments, the outer electrode layer 118 may be formed by Atomic Layer Deposition (ALD) or Chemical Vapor Deposition (CVD), which is a very conformal process due to filling a conductive material into the holes H13 (as shown in FIG. 3C detailed below). It has good interface properties between the conductive layers 104 and the memory layer 106, and a stable electrical temperature property between the conductive layers 104 and the memory layer 106. The resistance of the outer electrode layer 118 would be lower or higher than the resistance of the conductive layers 104, but is lower than the resistance of the protecting layer 108.

In some embodiments, the inner electrode layer 120 may be formed by Atomic Layer Deposition (ALD) or Chemical Vapor Deposition (CVD), which is a very conformal process due to filling a conductive material into the first opening H11 (as shown in FIG. 3B detailed below). It has good interface properties between the memory layer 106 and the protecting layer 108, and a stable electrical temperature property between the memory layer 106 and the protecting layer 108. The resistance of the inner electrode layer 120 would be lower or higher than the resistance of the conductive layers 104, but is lower than the resistance of the protecting layer 108.

It has good interface properties between the inner electrode layer 120 and the conductive pillar 110, and a stable electrical tem inner electrode layer 120 and the conductive pillar 110. The resistance of the protecting layer 108 would be higher than the resistance of the outer electrode layers 118, the inner electrode layer 120 and the conductive pillar 110 to reduce surge current.

The arrangement of the outer electrode layers 118 and the inner electrode layer 120 is optional, depending on the interface, temperature, electrical or mechanical properties. However, a resistance of the protecting layer 108 is a must to reduce surge current. In one embodiment, the semiconductor device includes outer electrode layers 118 but does not include the inner electrode layer 120. In one embodiment, the semiconductor device includes an inner electrode layer 120 but does not include the outer electrode layers 118.

Compared with embodiments in which the outer electrode layers 118 and the inner electrode layer 120 are not provided, the outer electrode layers 118 and the inner electrode layer 120 can provide a better interface performance between the memory layer 106 and the conductor (such as the conductive layers 104 or the conductive pillar 110), such as better electrical interface performance, mechanical interface performance or thermal interface performance. That is, the outer electrode layers 118 and the inner electrode layer 120 can respectively improve the electrical conduction between the memory layer 106 and the conductor, increase the adhesion between the memory layer 106 and the conductor, or prevent the metal ions in the conductor from dissipating into the memory layer 106.

FIGS. 3A to 3F illustrate a flow chart of a method for manufacturing the semiconductor device 20 of FIG. 2. That is, the method for manufacturing the semiconductor device 20 includes sequential steps as shown in FIGS. 3A to 3F.

Referring to FIG. 3A, a bottom plate 100 is provided and a stack ST is formed. The stack ST is stacked on the bottom plate 100 along the first direction D1. The stack ST includes a plurality of insulating layers 102 and a plurality of conductive layers 104. The insulating layers 102 and the conductive layers 104 are alternately stacked on the bottom plate 100 along the first direction D1.

Referring to FIG. 3B, a first opening H11 is formed through an etching process. The first opening H11 passes through at least a portion of the stack ST along the first direction D1. In the present embodiment, the bottom of the first opening H11 stops at the bottommost insulating layer 102 in the stack ST.

Referring to FIG. 3C, a plurality of holes H13 are formed through an etch-back process, such as Isotropic Reactive Ion Etching (Isotropic RIE). The holes H13 are connected to the first opening H11 and correspond to the conductive layers 104. That is, the etch-back process removes part of the conductive layers 104, causing the conductive layers 104 to recede and forming a hole H13 between two adjacent insulating layers 102.

Referring to the FIG. 3D, the conductive material is filled in the holes H13, on the top of the stack ST and in the first opening H11 through a deposition process to form the conductive material layer 118′. The conductive material layer 118′ is conformal to the top of the stack ST and the first opening H11. The material of the conductive material layer 118′ is the same as the material of the aforementioned outer electrode layers 118, and the description will not be repeated here.

Referring to FIG. 3E, the excess conductive material layer 118′ is removed through an etching process, such as isotropic reactive ion etching, to form the outer electrode layers 118 located in the holes H13.

Referring to FIG. 3F, the memory layer 106, the inner electrode layer 120, the protecting layer 108 and the conductive pillar 110 are sequentially formed in the first opening H11 (sidewalls and bottom) through multiple deposition processes. Next, a planarization process is performed so that the tops of the topmost insulating layer 102 of the stack ST, the memory layer 106, the inner electrode layer 120, the protecting layer 108 and the conductive pillar 110 are flush. The planarization process is, for example, chemical mechanical planarization (CMP). Multiple intersections between the memory layer 106 and the conductive layers 104 can form multiple memory cells, the memory cells corresponding to the same memory layer 106 are stacked in the first direction D1 to form a memory string, multiple memory layers 106 form multiple memory strings, and multiple memory strings form a memory array. Then, a capping layer 112 is formed to seal the memory array. The material of the capping layer 112 is, for example, oxide.

Thereafter, a contact 114 and a conductor layer 116 are formed. The contact passes through the capping layer 112 and is in electrical contact with the conductive pillar 110. The conductor layer 116 is disposed on the capping layer 112 and the contact 114 to form a semiconductor device as shown in FIG. 2.

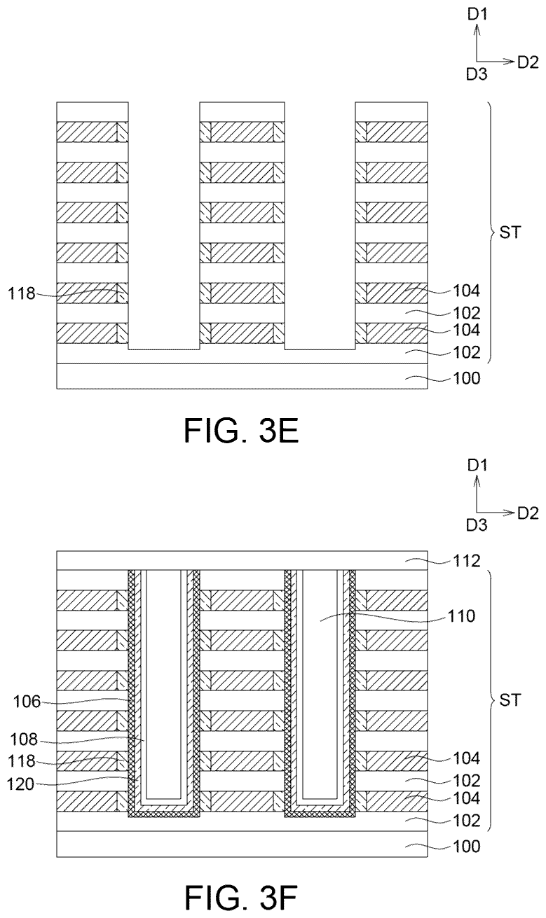

FIG. 4 illustrates a cross-sectional view of a semiconductor device 30 according to another embodiment of the present invention, in which the contacts 114 and the conductor layers 116 are omitted. The difference between the semiconductor device 30 and the semiconductor device 20 is that the appearance of the memory layer 306 of the semiconductor device 30 is different from the appearance of the memory layer 106, and other identical or similar parts will not be described in detail. Components in the semiconductor device 30 that are the same or similar to the semiconductor device 20 are labeled with the same or similar component symbols and have the same or similar structures, materials, and functions.

Referring to FIG. 4, the memory layer 306 extends discontinuously in the first direction D1 and overlaps the conductive layers 104 in the second direction D2 and the third direction D3. Two adjacent memory layers 306 are separated by an insulating layer 102.

Since the appearance of the memory layer 306 is different from the appearance of the memory layer 106, the method for manufacturing the memory layer 306 is slightly different from the method for manufacturing the memory layer 106. For example, after forming the first opening H31 (similar to the first opening H11 in FIG. 3B and having the same formation method as the first opening H11), holes H33 (similar to the holes H13 in FIG. 3C and having the same formation method as the holes H13) are formed. The first opening H31 passes through at least a part of the stack ST along the first direction D1. The width of the first opening H31 in the second direction D2 may be smaller than the width of the first opening H11 in the second direction D2. The holes H33 are in communication with the first opening H31 and correspond to the conductive layers 104. The width of the hole H33 in the second direction D2 may be greater than the width of the hole H13 in the second direction D2. For example, holes H33 are formed by an isotropic etching process to etch conductive layers 104 to form a deeper concave profile than holes H11. The isotropic etching process is a very high selective etch to conductive layers 104. The insulating layers 102 are almost intact. Thereafter, the conductive material is filled in the holes H33 by a deposition method (such as ALD or CVD). Then, an isotropic etching process is performed to the conductive material to pull back to form shallower concaves than the holes H33. That is, a portion of the holes H33 are exposed again by removing a portion of the conductive material to form the shallower concaves, and remaining portions of the conductive material form the outer electrode layers 118. The isotropic etching process is a very high selective etching process to the conductive material for forming the outer electrode layers 118. The insulating layers 102 are almost intact. The memory material is then filled into the portion of the holes H33 (shallower concaves), on the stack ST and in the first opening 31 to form a memory material layer (not shown) conformal to the stack ST and the first opening 31 by a deposition method (such as ALD or CVD process) to seal the holes H33 (shallower concaves), and then the excess memory material layer (not shown) is removed by an isotropic etching process, and the memory layer 306 in the holes H33 are formed. The isotropic etching process is a very high selective etching process to the memory material layer (not shown). The insulating layers 102 are almost intact. That is, the hole H33 can accommodate the external electrode layer 118 and the memory layer 306. After the memory layer 306 is formed, the inner electrode layer 120, the protecting layer 108 and the conductive pillars 110 are sequentially formed in the first opening H31 by the same method for manufacturing the inner electrode layer 120, the protecting layer 108 and the conductive pillar 110 as mentioned above.

In one embodiment, the method for manufacturing the stack ST of the semiconductor device 30 is the same as the aforementioned method for manufacturing the stack ST of the semiconductor device 20, but the present invention is not limited thereto. In another embodiment, the method for manufacturing the stack ST of the semiconductor device 30 is different from the aforementioned method for manufacturing the stack ST of the semiconductor device 20, as shown in FIG. 5.

FIG. 5 illustrates a cross-sectional view of a method for manufacturing the semiconductor device 30 of FIG. 4 according to another embodiment.

The forming step of the stack ST of the semiconductor device 30 may include steps described below. First, a stacked structure ST′ as shown in FIG. 5 is formed. The stacked structure ST′ includes a plurality of insulating layers 102 and a plurality of sacrificial layers 104′ alternately stacked along the first direction D1. The material of the insulating layers 102 can be same as the material of the insulating layers 102 mentioned above regarding FIG. 2. The material of the sacrificial layers 104′ may include nitrides, such as silicon nitride. After the conductive pillar 110 and the capping layer 112 are formed, the sacrificial layers 104′ are removed through an etching process, and a conductive material is filled in the removed positions of the sacrificial layers 104′ to form the conductive layers 104, wherein the material of the conductive layers 104 can be the same as the material of the conductive layers 104 mentioned above regarding FIG. 2.

It should be understood that the steps of forming the stack ST of the semiconductor devices 10 to 20 in FIGS. 1 and 2 can also be replaced by the method for manufacturing the stack ST described regarding FIG. 5.

In summary, the present invention provides a semiconductor device and a method for manufacturing the semiconductor device. Since the semiconductor device of the present invention includes a protecting layer, the protecting layer can locally increase the resistance of each of the memory cells, thereby reducing the surge current, protecting the components from being damaged by the surge current, and increasing the stability of the system.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A semiconductor device, comprising:
a bottom plate;
a stack stacked on the bottom plate along a first direction, wherein the stack comprises a plurality of insulating layers and a plurality of conductive layers alternately stacked on the bottom plate along the first direction;
a conductive pillar extending along the first direction and passing through at least a portion of the stack;
a protecting layer extending along the first direction, surrounding the conductive pillar and disposed between the conductive pillar and the conductive layers, wherein a resistance of the protecting layer is higher than a resistance of the conductive layers; and
a memory layer surrounding the protecting layer and disposed between the protecting layer and the conductive layers.

2. The semiconductor device according to claim 1, wherein the memory layer continuously extends along the first direction and overlaps the insulating layers and the conductive layers in a second direction and a third direction, wherein the first direction, the second direction and the third direction are perpendicular to each other.

3. The semiconductor device according to claim 1, wherein the memory layer discontinuously extends along the first direction and overlaps the insulating layers and the conductive layers in a second direction and a third direction, wherein the first direction, the second direction and the third direction are perpendicular to each other.

4. The semiconductor device according to claim 1, further comprising a plurality of outer electrode layers disposed between the conductive layers and the memory.

5. The semiconductor device according to claim 4, wherein the outer electrode layers surround the memory layer.

6. The semiconductor device according to claim 1, further comprising an inner electrode layer disposed between the memory layer and the protecting layer.

7. The semiconductor device according to claim 6, wherein the inner electrode layer surrounds the protecting layer.

8. The semiconductor device according to claim 1, further comprising a conductor layer disposed on the stack and electrically connected to the conductive pillar.

9. The semiconductor device according to claim 1, wherein the protecting layer continuously extends along the first direction and overlaps the insulating layers and the conductive layers along a second direction and a third direction, wherein the first direction, the second direction and the third direction are perpendicular to each other.

10. The semiconductor device according to claim 1, wherein the memory layer serves as an ovonic threshold switching.

11. A semiconductor device, comprising:
providing a bottom plate;
forming a stack stacked on the bottom plate along a first direction, wherein the stack comprises a plurality of insulating layers and a plurality of conductive layers alternately stacked on the bottom plate along the first direction;
forming a conductive pillar extending along the first direction and passing through at least a portion of the stack;
forming a protecting layer extending along the first direction, surrounding the conductive pillar and disposed between the conductive pillar and the conductive layers, wherein a resistance of the protecting layer is higher than a resistance of the conductive layers; and
forming a memory layer surrounding the protecting layer and disposed between the protecting layer and the conductive layers.

12. The method according to claim 11, further comprising:
forming a first opening passing through at least a portion of the stack along the first direction; and
sequentially forming the memory layer and the protecting layer in the first opening.

13. The method according to claim 12, wherein the memory layer continuously extends along the first direction and overlaps the insulating layers and the conductive layers in a second direction and a third direction, wherein the first direction, the second direction and the third direction are perpendicular to each other.

14. The method according to claim 12, further comprising:
forming a plurality of holes in communication with the first opening and corresponding to the conductive layers; and
filling a conductive material in the holes to form a plurality of outer electrode layers.

15. The method according to claim 12, further comprising forming an inner electrode layer between the memory layer and the protecting layer.

16. The method according to claim 11, further comprising:
forming a first opening passing through at least a portion of the stack;
forming a plurality of holes in communication with the first opening and corresponding to the conductive layers;
filling a conductive material in the holes;
removing a portion of the conductive material to expose a portion of the holes, and remaining portions of the conductive material forming a plurality of outer electrode layers;
filling a memory material into the portion of the holes to form the memory layer; and
forming a protecting layer in the first opening.

17. The method according to claim 11, wherein the memory layer discontinuously extends along the first direction and overlaps the insulating layers and the conductive layers in a second direction and a third direction, wherein the first direction, the second direction and the third direction are perpendicular to each other.

18. The method according to claim 16, further comprising filling a conductive material into the holes to form a plurality of outer electrode layers.

19. The method according to claim 16, further comprising forming an inner electrode layer between the memory layer and the protecting layer.

20. The method according to claim 11, wherein the step for forming the stack comprises:
forming a stacked structure, the stacked structure comprises a plurality of insulating layers and a plurality of sacrificial layers alternately stacked along the first direction; and
removing the sacrificial layers and filling a conductive material into removed positions of the sacrificial layers to form the conductive layers.
